(19) United States
(12) Patent Application Publication
(10) Pub. No.: US 2002/0132461 A1
(43) Pub. Date: Sep. 19, 2002

(54) Semiconductor device having bump electrodes with a stress dissipating structure and method of manufacturing the same

(75) Inventor: Masayasu Kizaki, Iruma-shi (JP)

Correspondence Address: FRISHAUF, HOLTZ, GOODMAN & CHICK, PC, 767 THIRD AVENUE, 25TH FLOOR, NEW YORK, NY, 10017-2023, US

(73) Assignee: Casio Computer Co., Ltd., Tokyo (JP)

(21) Appl. No.: 10/099,306

(22) Filed: Mar. 14, 2002

(30) Foreign Application Priority Data
Mar. 19, 2001 (JP) 2001-077772

(51) Int. Cl. H01L 23/48

(52) U.S. Cl. 438/612; 257/737

(57) ABSTRACT

A semiconductor device comprises a semiconductor substrate, a plurality of bump electrodes formed on the semiconductor substrate, and a sealing film having a top surface located higher than a top surface of each bump electrode and an opening for exposing the top surface of each bump electrode.

### CROSS-REFERENCE TO RELATED APPLICATIONS

This application is based upon and claims the benefit of priority from the prior Japanese Patent Application No. 2001-077772, filed Mar. 19, 2001, the entire contents of which are incorporated herein by reference.

### BACKGROUND OF THE INVENTION

1. Field of the Invention

The present invention relates to a semiconductor device wherein a plurality of bump electrodes are formed on one side of a semiconductor substrate made of silicon, etc., and a sealing film is formed between the bump electrodes. The invention relates more particularly to a semiconductor device having a structure for damping stress that acts on a connecting element formed on each bump electrode, by making the top surface of each bump electrode lower than the top surface of the sealing film, and a method of manufacturing the same.

2. Description of the Related Art

An example of the semiconductor device having the above-described stress damping structure, which is called a CSP (chip size package), is shown in FIG. 8. In the semiconductor device shown in FIG. 8, a plurality of connection pads 2 are formed on a top surface of a semiconductor substrate 1 made of silicon, etc. An insulating film 3 is formed on the substrate and the connection pads, excluding the central portion of each connection pad 2. A wiring 5 is formed to extend from the top surface of the connection pad 2 exposed through an opening 4 formed in the insulating film 3 to a predetermined portion on the top surface of the insulating film 3. A bump electrode 6 is formed on the end of the wiring 5. A sealing film 7 is formed on the entire top surface of the assembly, excluding on the bump electrode 6, such that the top surface of the sealing film 7 is higher than that of the bump electrode 6. An opening 8 is formed in the sealing film 7 above the bump electrode. A solder ball 9 is provided within the opening such that the lower portion of the solder ball 9 is conductively connected to the bump electrode 6.

In this case, the top surface of the bump electrode 6 is lower than the top surface of the sealing film 7. The solder ball 9 is formed, being conductively connected to the bump electrode 6, within and above the opening 8 formed in the sealing film 7. This prevents cracks from easily occurring at the interface between the bump electrode 6 and the solder ball 9, if the semiconductor device is mounted on a circuit board (not shown) and afterwards subjected to a temperature cycling test, etc. These cracks occur due to the stress caused by the different thermal expansion coefficients of the semiconductor substrate 1 and the circuit board.

Next, an example of a method of manufacturing the semiconductor device will be explained referring to FIGS. 9 to 12 in order. To start with, a semiconductor device having the following structure as shown in FIG. 9 is prepared: the connection pads 2 are formed on the top surface of each semiconductor substrate 1 of a wafer; the insulating film 3 is formed on the top surface of the connection pad 2, excluding the central portion of the connection pad 2; the wiring 5 is formed to extend from the top surface of the connection pad 2 exposed through the opening 4 formed in the insulating film 3 to a predetermined portion of the top surface of the insulating film 3; and the bump electrode 6 having a height of about 120 μm, as an example, is formed over the top surface of the pad portion at the end of the wiring 5.

Next, as shown in FIG. 10, the sealing film 7 made of an epoxy-based resin is formed by transfer molding, dispenser method, dipping method, printing method, etc., on the entire top surface of the insulating film 3 including the bump electrode 6 and the wiring 5 such that the thickness of the film 7 may be a little thicker than the height of the bump electrode 6. Thus, in this state, the top surface of the bump electrode 6 is covered with the sealing film 7.

Then, as shown in FIG. 11, the top surface side of the sealing film 7 and the top surface side of the bump electrode 6 are polished away, so that the top surface of the bump electrode 6 is exposed. The exposed top surface of the bump electrode 6 is thus flush with the top surface of the sealing film 7. The polishing in this case not only exposes the top surface of the bump electrode 6 but also finishes the surface (top surface) of the sealing film 7. Thus, the top surface side of the bump electrode 6 is polished by about 30 μm. Therefore, the height of the bump electrode 6 in this state is about 90 μm.

As shown in FIG. 12, the top surface side of the bump electrode 6 is etched by about 30 μm, by a half-etching process, to form the opening 8 in the sealing film 7. Thus, the height of the bump electrode 6 in this state is about 60 μm. Next, as shown in FIG. 8, the solder ball 9 is formed, being conductively connected to the bump electrode 6, within and above the opening 8 formed in the sealing film 7. A dicing process is performed to the wafer, thereby obtaining semiconductor devices, each comprising an individual chip.

In the conventional semiconductor device, the height of the bump electrode 6 is initially about 120 μm, which is relatively high. However, after a polishing process, also serving as surface finishing, and a half-etching process are performed, the height of the bump electrode 6 is about 60 μm, half the original height. There is a problem that the stress is insufficiently damped by the bump electrode 6 itself. It is conceivable that the original height of the bump electrode 6 is made higher. However, a photoresist film used in forming the bump electrodes 6 from a plating layer becomes thick, thus it is hard to uniformize translucency in the thickness direction at the time of applying the photoresist to the metal layer and at the time of exposure. The formation by photo lithography has limits. Even if the problems of formation of the photoresist film and exposure are overcome, production efficiency is obviously low using a method wherein the bump electrode is formed higher and then etched by about 60 μm. Variations not only in the height of the bump electrodes 6, but also in the height of the solder balls 9 occur due to the half-etching process. This causes faulty connection with the circuit board.

### BRIEF SUMMARY OF THE INVENTION

An object of the present invention is to provide a semiconductor device having bump electrodes with a stress damping structure, wherein the height of the electrodes is efficiently made higher and uniform.

According to one aspect of the present invention, there is provided a semiconductor device wherein a sealing film is formed thicker than the height of each bump electrode, and an opening for exposing the top surface of each bump electrode is formed in the sealing film.

According to the above structure, the top surface of each bump electrode is located lower than the top surface of the sealing film. Therefore, the bump electrode has a function of damp stress that acts on the interface with a connect material formed on each bump electrode. The opening of the sealing film can be formed without performing an etching process which increases variation in the height of the bump electrodes. Thus, the height of the bump electrodes can be made uniform, and efficient production can be achieved.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is an enlarged sectional view showing a semiconductor device according to a first embodiment of the present invention;

FIG. 2 is an enlarged sectional view relating to a method of manufacturing the semiconductor device shown in FIG. 1 and for explaining a first manufacture step;

FIG. 3 is an enlarged sectional view for explaining a manufacture step following the step of FIG. 2;

FIG. 4 is an enlarged sectional view for explaining a manufacture step following the step of FIG. 3;

FIG. 5 is an enlarged sectional view for explaining a manufacture step following the step of FIG. 4;

FIG. 6 is an enlarged sectional view showing a semiconductor device according to a modification of the first embodiment;

FIG. 7 is an enlarged sectional view showing a semiconductor device according to a second embodiment of the present invention;

FIG. 8 is an enlarged sectional view showing a conventional semiconductor device;

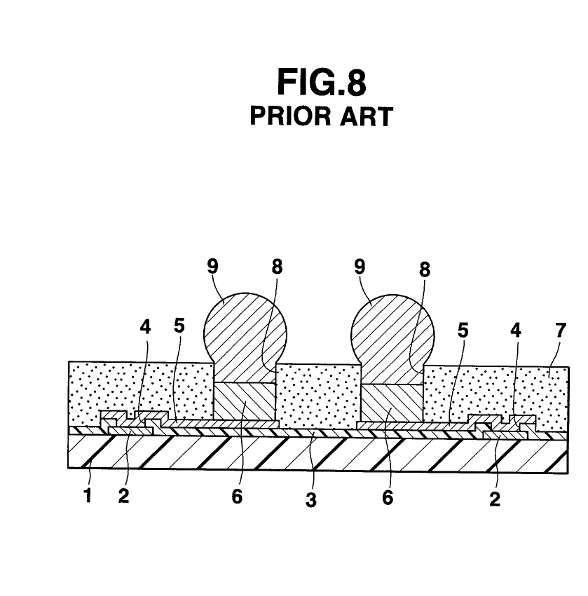

FIG. 9 is an enlarged sectional view relating to a method of manufacturing the semiconductor device shown in FIG. 8 and for explaining a first manufacture step;

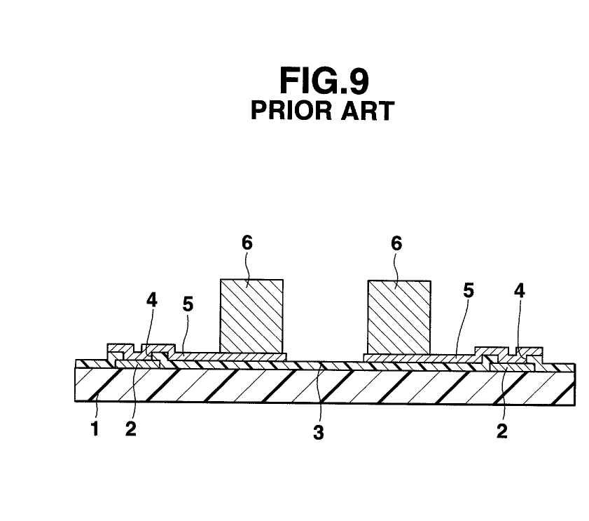

FIG. 10 is an enlarged sectional view for explaining a manufacture step following the step of FIG. 9;

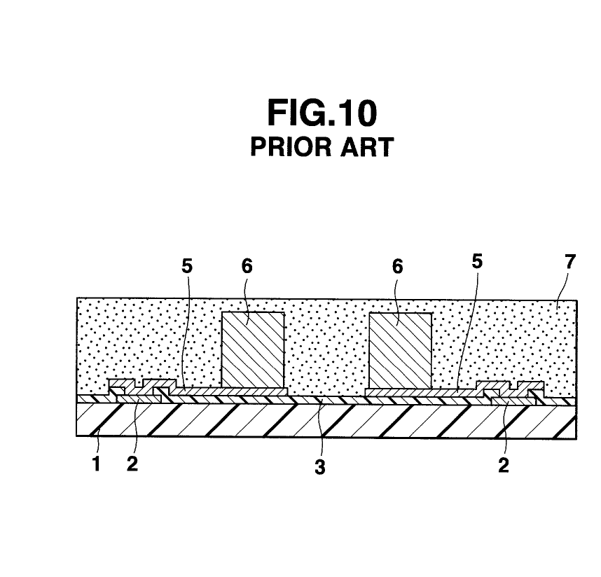

FIG. 11 is an enlarged sectional view for explaining a manufacture step following the step of FIG. 10; and

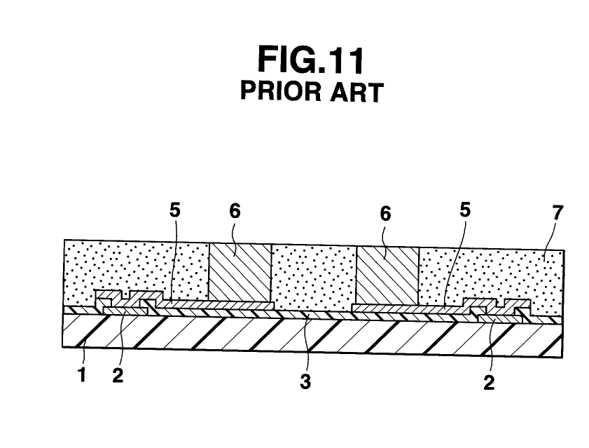

FIG. 12 is an enlarged sectional view for explaining a manufacture step following the step of FIG. 11.

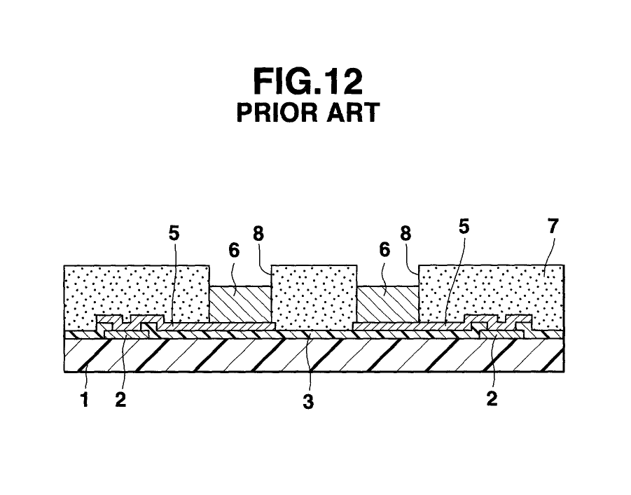

### DETAILED DESCRIPTION OF THE INVENTION

First Embodiment

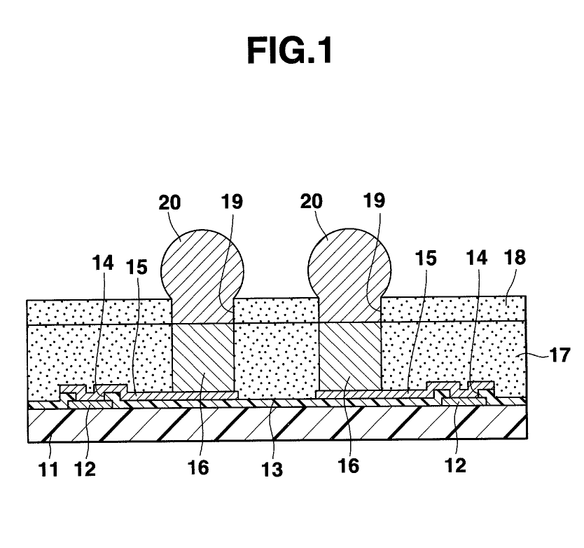

FIG. 1 is an enlarged sectional view showing a semiconductor device according to one embodiment of the present invention. The structure of the semiconductor device will be described below.

A plurality of connection pads 12 are formed on a top surface of a semiconductor substrate 11 made of silicon, etc. An insulating film 13 is formed on the substrate and the connection pad, excluding the central portion of the connection pad 12. An opening 14 is formed in the insulating film 13 for exposing the connection pad 12. A wiring 15 extends from the top surface of the connection pad 12, through the opening 14, onto the insulating film 13. The wiring 15 is formed of, e.g., copper, etc. A columnar bump electrode 16 made of a conductive material such as copper, etc., is formed on the top surface at the end of the wiring 15 and over the extending portion of the pad portion (although not shown in the figure, the connection pad 12 extends in the central direction of the substrate). A first sealing film 17 is formed between the columnar bump electrodes 16, throughout the upward entire semiconductor substrate 11 (specifically, on the exposed surfaces of the insulating film 13 and wiring 15). The thickness of the first sealing film 17 is set such that the top surface of the film 17 is substantially flush with the top surface of each bump electrode 16. A second sealing film 18 having an opening 19 for exposing the top surface of each bump electrode is formed on the first sealing film 17. A solder ball (low-melting metal layer) 20 is formed, being conductively connected to the bump electrode 16, within and above the opening 19 formed in the second sealing film 18.

In this case, since the top surface of the bump electrode 16 is flush with the top surface of the sealing film 17, and solder ball 20 is formed, being conductively connected to the bump electrode 16, within and above the opening 19 formed in the second sealing film 18 formed on the first sealing film 17, there may prevents cracks from easily occurring at the interface between the bump electrode 16 and the solder ball 20, if the semiconductor device is mounted on a circuit board (not shown) and afterwards subjected to a temperature cycling test, etc. These cracks would occur due to the stress caused by the different thermal expansion coefficients of the semiconductor substrate 11 and the circuit board.

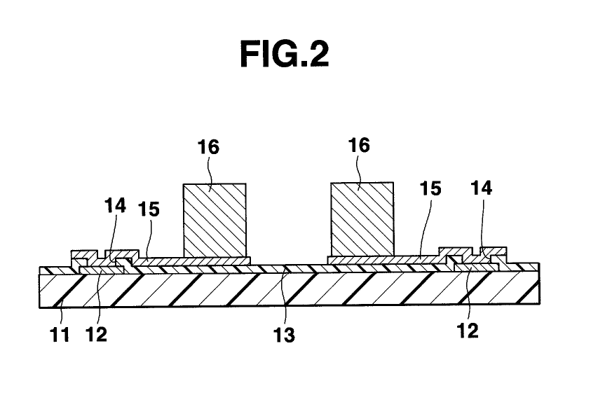

Next, an example of a method of manufacturing the semiconductor device will be explained referring to FIGS. 2 to 5 in order. To start with, a semiconductor device having the following structure as shown in FIG. 2 is prepared: the connection pad 12 made of an aluminum-based metal, etc., is formed on the top surface of each semiconductor substrate 11 of a wafer state; the insulating film 13 is formed on the top surface of the connection pad 12, excluding the central portion of the connection pad 12; the wiring 15 is formed to extend from the top surface of the connection pad 12 exposed through the opening 14 formed in the insulating film 13 to a predetermined portion of the top surface of the insulating film 13; and the columnar bump electrode 16 having a height of about 120 μm, as an example, is formed on the top surface of the pad portion at the end of the wiring 15. The bump electrode 16 is formed by photo lithography. For example, the whole surface on the insulating film 13 is covered with a metal film for wiring, by sputtering, etc. A photoresist film is formed on the metal film. An opening for bump formation is formed in the photoresist film. The bump electrode 16 is formed by electrolytic plating, using the metal film formed on the insulating film 13 as one electrode. After the bump electrode is formed, the photoresist film is removed, and the metal film is patterned by photo lithography. Thereby the wiring 15 is formed (the state shown in FIG. 2).

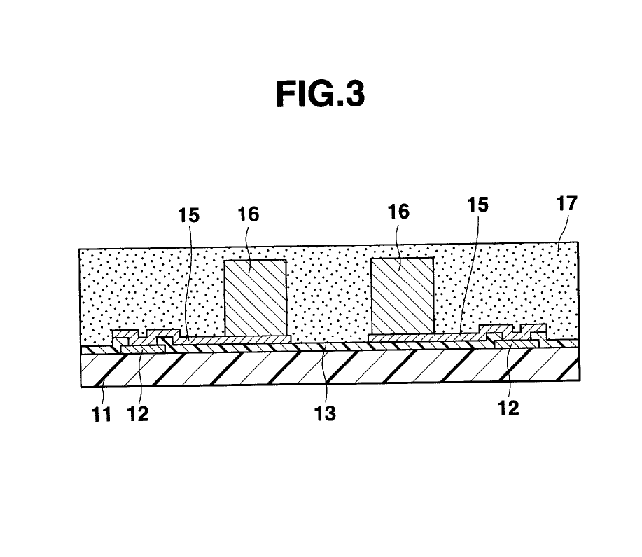

Next, as shown in FIG. 3, the first sealing film 17 made of an epoxy-based resin is formed by transfer molding, dispenser method, dipping method, printing method, etc., on the entire top surface of the insulating film 13 including the bump electrode 16 and the wiring 15 such that the thickness of the film 17 may be a little thicker than the height of the bump electrode 16. Thus, in this state, the top surface of each bump electrode 16 is covered with the first sealing film 17.

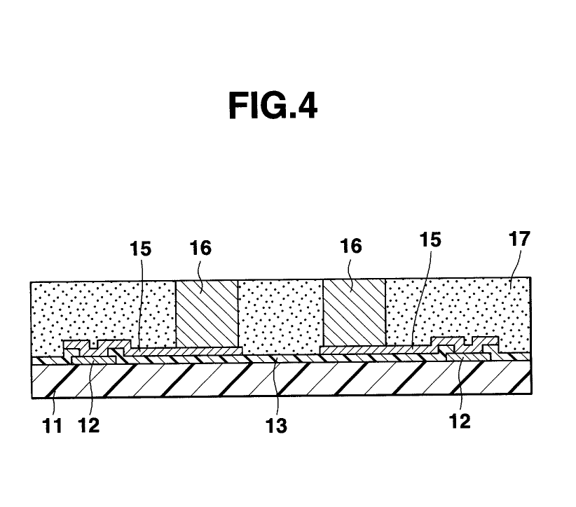

Then, as shown in FIG. 4, the top surface side of the first sealing film 17 and the top surface side of each bump electrode 16 are polished away, so that, the top surface of the bump electrode 16 is exposed. The top surface of the exposed bump electrode 16 is thus flush with the top surface of the sealing film 17. In this case, it is not necessary to finish the surface (top surface) of the first sealing film 17 since the second sealing film described below is formed. The polishing in this case only exposes the top surface of each bump electrode 16 and makes the top surface of the exposed bump electrode 16 flush with the top surface of the sealing film 17. Thus, the top surface side of the bump electrode 16 is polished by, for example, about 5 to 20 μm, less than in the prior art (about 30 μm). Therefore, the height of the bump electrode 16 in this state is about 100 to 115 μm.

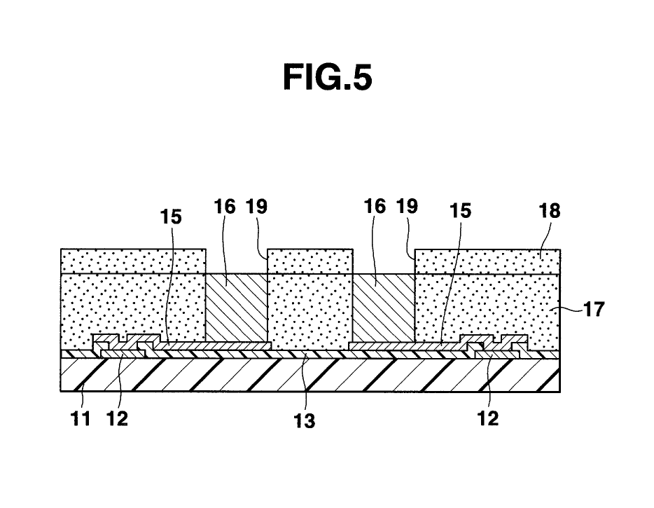

Next, as shown in FIG. 5, the second sealing film 18 is formed on the top surface of the first sealing film 17 by screen printing, photo lithography, etc. The second sealing film 18 is made of an epoxy-based resin and has a thickness of about 10 to 50 μm, preferably 20 to 30 μm (no sealing film is formed on the top surface of the bump electrode 16). In this state, the opening 19 is formed in the portion of the second sealing film 18 corresponding in position to the top surface of the bump electrode 16. Then, as shown in FIG. 1, the solder ball 20 is formed, being conductively connected to the bump electrode 16, within and above the opening 19 formed in the second sealing film 18. The solder ball 20 may be formed by directly depositing a solder ball onto each bump electrode, or by a reflow method, involving a solder ball being formed by depositing solder paste onto each bump electrode. In the reflow method, the solder paste melted by reflowing is formed in a ball shape due to surface tension. Then, the wafer is separated by a dicing process, thereby obtaining semiconductor devices each comprising an individual chip.

In the semiconductor device thus obtained, the first sealing film 17 is formed such that the top surface thereof is flush with the top surface of each bump electrode 16, by polishing. The second sealing film 18 is formed on the first sealing film 17 to have the opening 19 at the portion thereof corresponding in position to the top surface of the bump electrode 16. Thus, the top surface of each bump electrode 16 can be lower than the top surface of the sealing film 18. In addition, the height of the bump electrode 16 is the same as the thickness of the first sealing film 17. Therefore, the height of the bump electrodes 16 can be increased and can be made uniform.

More specifically, in the above embodiment, the original height of the bump electrode 16 is about 120 μm, while the ultimate height is about 100 to 115 μm, which is a little lower than the original height. Compared with the ultimate height of about 60 μm in the prior art, the height can be considerably increased. As a result, the stress is sufficiently damped by the bump electrode 16 itself. Since the height of the bump electrodes 16 can be made uniform, the height of the solder balls 20 can also be uniform. This prevents problems occurring in the conductive connection with the circuit board.

By polishing the top surface side of the first sealing film 17, the top surface of each bump electrode 16 is flush with the top surface of the first sealing film 17. The second sealing film 18 is formed on the first sealing film 17 to have the opening 19 at the portion thereof corresponding in position to the top surface of the bump electrode 16. Thus, the second sealing film 18 may be formed by screen printing, photo lithography, etc., instead of the half-etching process in the prior art. This thus simplifies the manufacturing process.

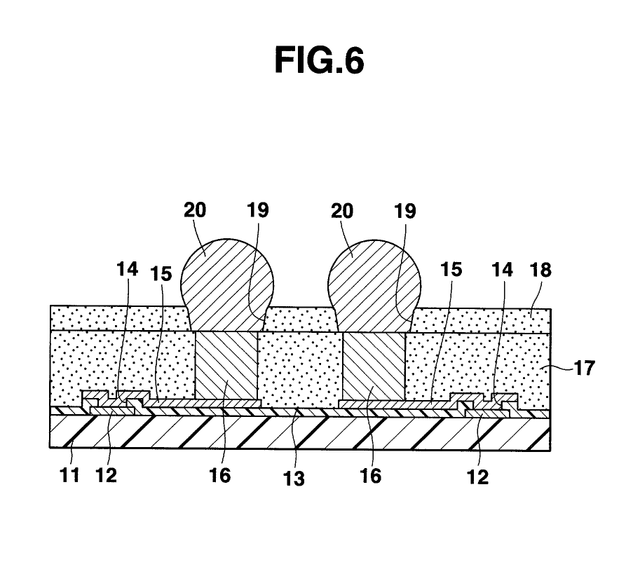

FIG. 6 is an enlarged sectional view showing a modification of the semiconductor device shown in FIG. 1. In this modification, the dimensions (plane dimensions) of the opening 19 formed in the second sealing film 18 are made one size larger than the dimensions (plane dimensions) of the bump electrode 16. This allows the solder ball 20 as a whole to reliably come into contact with the bump electrode, even if there is alignment deviation. In order to reduce the inner stress of the solder ball 20 formed within the opening 19, the side faces of the opening 19 may be inclined such that the opening widens upwardly. In FIG. 6, the dimensions of the opening 19 formed in the second sealing film 18 are larger than those of the bump electrode 16, and the side faces of the opening 19 are inclined such that the opening widens upwardly. However, the side faces of the opening 19 may be substantially vertical, as in FIG. 1. The horizontal dimensions of the opening 19 may be substantially the same as those of the bump electrode 16, as in FIG. 1, and the side faces may be inclined such that the opening widens upwardly. The opening 19 may be formed by laser, after the second sealing film 18 is formed over the entire area of the first sealing film 17 and the bump electrode 16.

Second Embodiment

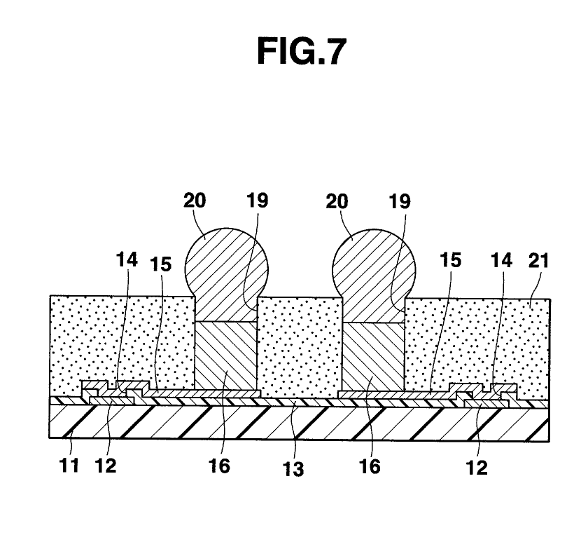

FIG. 7 is an enlarged sectional view showing a semiconductor device according to a second embodiment of the present invention. The difference with the first embodiment is that a sealing film 21 comprises one layer. The top surface of each bump electrode 16 is located lower than the top surface of the sealing film 21 comprising one layer. The method of manufacturing the semiconductor device according to the second embodiment will be explained. The photoresist film is formed on the top surface of the semiconductor substrate 11 having the connection pad 12, insulating film 13, and wiring 15. The opening is formed by photo lithography, at the portion of the photoresist film on which the bump electrode 16 is formed (the photoresist film is not shown). Then the bump electrode 16 is formed by plating, etc. After the photoresist film is removed, the height of each bump electrode 16 is made uniform by polishing the top surface of each bump electrode 16. The sealing film 21 is formed thicker than the bump electrode 16 by transfer molding, dispenser method, dipping method, printing method, etc. (the thickness of the sealing film in this case is therefore obtained by adding the thickness of the first sealing film 17 in FIGS. 1 and 6 to the thickness of the second sealing film 18). Then the top surface of the sealing film is polished down according to necessity to flatten it. After that, a laser beam is applied to the sealing film to form the opening 19 for exposing the bump electrode 16. The steps that follow this step are the same as those in the first embodiment. In the second embodiment, too, the dimensions (plane dimensions) of the opening 19 may be larger than the dimensions (plane dimensions) of the bump electrode 16, as shown in FIG. 6. The side faces of the opening 19 also may be inclined such that the opening widens upwardly.

In each embodiment, instead of the solder ball 20 on the bump electrode 16, a low-melting metal layer having a uniform thickness may be provided by plating, sputtering, printing, etc. Such a solder ball or low-melting metal layer may be formed not on the semiconductor device but on a connection terminal of the circuit board on which the semiconductor device is mounted. In the above embodiments, the second sealing film 18 having the opening 19 at the portion thereof corresponding in position to the top surface of the bump electrode 16 is formed on the first sealing film 17. Immediately after that, the solder ball 20 is formed within and above the opening 19. However, if the top surface of the bump electrode 16 is oxidized, wet etching or dry etching may be used to perform a metal layer formation process, such as nickel plating, for preventing oxide film occurrence, in addition to the process for removing an oxide film from the top surface of the bump electrode 16. Afterwards, the solder ball 20 may be formed. “Metal layer formation” refers to, for example, nickel plating. If the oxide film removal process is performed, the height of the bump electrode 16 is lowered to some extent. However, the amount is small, and the top surface of the bump electrode 16 is substantially flush with the top surface of the first sealing film. Thus, a similar advantage can be obtained. The dimensions (plane dimensions) of the opening 19 of the second sealing film 18 may be one size smaller than those of the top surface of the bump electrode 16. In the above embodiment, instead of forming the solder ball 20, the bump electrode 16 may be conductively connected, through an anisotropic conductive bonding agent, to the connection terminal of the circuit board.

As described above, according to the present invention, the top surface of each bump electrode is located lower than the top surface of the sealing film. Thus, the bump electrode has a function of dissipating stress that acts on the interface with a joining material formed on the bump electrode. The opening of the sealing film can be formed without performing an etching process which increases variation in the height of the bump electrodes. Thus, the height of the bump electrodes can be made uniform, and efficient production can be achieved.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
a plurality of bump electrodes formed distant from each other on an upper side of the semiconductor substrate and each having a top surface;
a first sealing film formed on the upper side of the semiconductor device between the bump electrodes, having a top surface being substantially flush with the top surface of each bump electrode; and
a second sealing film formed on the first sealing film, having an opening in a portion thereof corresponding in position to the top surface of each bump electrode.

2. A semiconductor device according to claim 1, wherein a low-melting metal layer is formed within and above the opening of the second sealing film.

3. A semiconductor device according to claim 2, wherein the low-melting metal layer is a solder ball.

4. A semiconductor device according to claim 1, wherein plane dimensions of the opening of the second sealing film are larger than plane dimensions of each bump electrode.

5. A semiconductor device according to claim 1, wherein the side faces of the opening of the second sealing film are inclined such that the opening widens upwardly.

6. A semiconductor device comprising:
a semiconductor substrate;
a plurality of bump electrodes provided at predetermined intervals on an upper side of the semiconductor substrate; and
a sealing film provided on the upper side of the semiconductor substrate between the bump electrodes, and having a top surface located higher than the top surface of each bump electrode and an opening for exposing the top surface of each bump electrode.

7. A semiconductor device according to claim 6, wherein a low-melting metal layer is formed within and above the opening of the sealing film.

8. A semiconductor device according to claim 7, wherein the low-melting metal layer is a solder ball.

9. A method of manufacturing a semiconductor device comprising:
forming a plurality of bump electrodes on an upper side of a semiconductor substrate;
forming a first sealing film on a top surface of each bump electrode and on the upper side of the semiconductor substrate;
polishing a side of a top surface of the first sealing film to expose the top surface of each bump electrode;
polishing the top surface of the exposed bump electrode and the top surface of the first sealing film such that these top surfaces are flush with each other; and
forming a second sealing film on the first sealing film to have an opening in a portion thereof corresponding in position to the top surface of each bump electrode.

10. A method according to claim 9, wherein in said polishing of the top surface of the bump electrode, the top surface of the bump electrode is polished by about 5 to 20 μm.

11. A method according to claim 9, wherein in said forming of the second sealing film, the second sealing film is formed by screen printing or photo lithography.

12. A method according to claim 9, further comprising forming a low-melting metal layer within and above the opening of the second sealing film.

13. A method of manufacturing a semiconductor device comprising:
forming bump electrodes on an upper side of a semiconductor substrate;
forming, on the upper side of the semiconductor substrate including the bump electrodes, a sealing film thicker than the height of each bump electrode; and
forming, in the sealing film, an opening for exposing a top surface of each bump electrode.

14. A method according to claim 13, wherein in said forming the bump electrodes, an opening is formed at a predetermined portion of a photoresist film and each electrode is formed within the opening by plating.

15. A method according to claim 14, further comprising making the height of the bump electrodes uniform, after removing the photoresist film.

16. A method according to claim 13, wherein the top surface of the sealing film is flattened, and afterwards the opening is formed in the sealing film.

17. A method according to claim 13, wherein the opening is formed by applying a laser beam to the sealing film.
